(19) United States
(12) Patent Application Publication
(10) Pub. No.: US 2026/0293400 A1
(43) Pub. Date: Sep. 24, 2026

(54) ELECTRONIC DEVICE

(71) Applicant: Innolux Corporation, Miaoli County (TW)

(72) Inventor: Shuhei Hosaka, Miaoli County (TW)

(73) Assignee: Innolux Corporation, Miaoli County (TW)

(21) Appl. No.: 19/084,794

(22) Filed: Mar. 20, 2025

(51) Int. Cl. H10H 29/49

(52) U.S. Cl. CPC H10H 29/49

(57) ABSTRACT

An electronic device includes a plurality of first main lines, a plurality of first branch lines and a first circuit group. The plurality of first main lines extend along a first direction. The plurality of first branch lines are respectively electrically connected to the plurality of first main lines and extend along a second direction perpendicular to the first direction. The first circuit group is disposed on a side of the plurality of first main lines and includes a first circuit and a second circuit. The first circuit is electrically connected to one of the plurality of first branch lines. The second circuit is electrically connected to another one of the plurality of first branch lines. The first circuit and the second circuit are arranged along the second direction.

### BACKGROUND

### Technical Field

This disclosure relates to an electronic device.

### Description of Related Art

For narrow-border or even borderless electronic devices, functional circuits (e.g., driving circuits, inspection circuits, electrostatic discharge protection (ESD) circuits, etc.) need to be integrated into the active region or pixel region. Therefore, the active region or pixel region needs to be re-layouted.

### SUMMARY

The disclosure provides an electronic device that helps to achieve a narrow border or even no border.

In an embodiment of the disclosure, an electronic device includes a plurality of first main lines, a plurality of first branch lines and a first circuit group. The plurality of first main lines extend along a first direction. The plurality of first branch lines are respectively electrically connected to the plurality of first main lines and extend along a second direction perpendicular to the first direction. The first circuit group is disposed on a side of the plurality of first main lines and includes a first circuit and a second circuit. The first circuit is electrically connected to one of the plurality of first branch lines. The second circuit is electrically connected to another one of the plurality of first branch lines. The first circuit and the second circuit are arranged along the second direction.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate example embodiments of the disclosure and, together with the description, serve to explain the principles of the disclosure.

FIG. 1 is a partial top view of an electronic device according to some embodiments of the disclosure.

FIG. 2 is a simple circuit diagram of a circuit in FIG. 1.

FIG. 3 is a partial top view of an electronic device according to some embodiments of the disclosure.

FIG. 4 is an enlarged view corresponding to four pixels in FIG. 3.

FIG. 5 is a partial top view of an electronic device according to some embodiments of the disclosure.

FIG. 6 is a partial top view of an electronic device according to some embodiments of the disclosure.

### DESCRIPTION OF THE EMBODIMENTS

Reference will now be made in detail to the exemplary embodiments of the disclosure, examples of which are illustrated in the accompanying drawings. Whenever possible, the same reference numerals are used in the drawings and descriptions to refer to the same or similar parts.

Throughout this specification and the claims, certain words are used to refer to specific components. One of ordinary skill in the art will appreciate that manufacturers of electronic devices may refer to the same component by different names. This disclosure is not intended to differentiate between components that have the same function but have different names. In the following description and claims, the words “include” and “comprise” are open-ended terms and should therefore be interpreted to mean “includes, but is not limited to . . . ”.

The directional terms mentioned in this disclosure, such as “up”, “down”, “front”, “back”, “left”, “right”, etc., are only for reference to the directions in the accompanying drawings. Accordingly, the directional terms used are illustrative and not limiting of the disclosure. In the drawings, each figure illustrates the general features of methods, structures, and/or materials used in particular embodiments. However, these drawings should not be interpreted as defining or limiting the scope or nature encompassed by these embodiments. For example, the relative sizes, thicknesses, and locations of various layers, regions, and/or structures may be reduced or exaggerated for clarity.

One structure (or layer, component, substrate) described in the disclosure is located on/above another structure (or layer, component, substrate), which may mean that the two structures are adjacent to each other and are directly connected, or that the two structures are adjacent to each other and are not directly connected. Non-directly connected means that there is at least one intermediary structure (or intermediary layer, intermediary component, intermediary substrate, intermediary spacer) between the two structures, with the lower surface of one structure adjacent to or directly connected to the upper surface of the intermediary structure, and the upper surface of the other structure adjacent to or directly connected to the lower surface of the intermediary structure. The intermediary structure may be a single or multi-layered solid or non-solid structure, without limitation. In the disclosure, when a structure is disposed “on” other structures, it may mean that a structure is “directly” on the other structures, or that a structure is “indirectly” on the other structures, that is, a structure and other structures have at least one other structure sandwiched between them.

The terms “approximately”, “substantially” or “generally” are generally interpreted as being within 10% of the given value or range, or within 5%, 3%, 2%, 1% or 0.5% of the given value or range. In addition, the terms “the range is from the first value to the second value”, “the range is between the first value and the second value” indicate that the range includes the first value, the second value, and other values in between.

The ordinal numbers used in the specification and claims, such as “first” and “second”, are used to qualify the components, and do not in themselves imply or represent any previous ordinal number of the component or components, nor do they represent the order of one component or component with another, or the order of the manufacturing method. The use of these numbers is intended only to enable a component with a certain designation to be clearly distinguished from another component with the same designation. The same terminology may not be used in the claims and the specification. Accordingly, the first component in the specification may be the second component in the claims.

The electrical connection or coupling described in the disclosure may refer to either a direct connection or an indirect connection, in which the terminals of the two circuit elements are directly connected or connected to each other by a conductor line, or an indirect connection in which the terminals of the two circuit elements are connected by a switch, a diode, a capacitor, an inductor, a resistor, or any other suitable component, or a combination of the foregoing, without limitation.

In this disclosure, the thickness, length, and width can be measured by using an optical microscope (OM), and the thickness or width can be measured by cross-sectional images in an electron microscope, but not limited thereto. In addition, there may be a certain amount of error between any two values or directions used for comparison. Furthermore, the expression “the given range is the first value to the second value”, “the given range falls within the range of the first value to the second value” or “the given range is between the first value to the second value” means that the given range includes the first value, the second value, and other values in between. If the first direction is perpendicular to the second direction, the angle between the first direction and the second direction can be between 80 degrees and 100 degrees; if the first direction is parallel to the second direction, the angle between the first direction and the second direction can be between 0 degrees and 10 degrees.

Unless otherwise defined, all terms used herein, including technical and scientific terms, have the same meanings as are commonly understood by those skilled in the art. It is to be understood that these terms, such as those defined in commonly used dictionaries, should be interpreted as having a meaning consistent with the context or background of the relevant technology and the present disclosure, and should not be interpreted in an idealized or overly formalized manner, except as specifically defined in the embodiments of the present disclosure.

In the disclosure, the electronic device may include a display device, a backlight device, an antenna device, a packaging device, a sensing device, or a splicing device, but not limited thereto. The electronic device may be a bendable or flexible electronic device. The display device can be a non-self-illuminating display device or a self-illuminating display device. The display device may include, for example, liquid crystal, light-emitting diode, fluorescence, phosphor, quantum dot (QD), other suitable display media, or a combination of the above. The antenna device may include, for example, a reconfigurable intelligent surface (RIS), a frequency selective surface (FSS), a radio frequency filter (RF-Filter), a polarizer, a resonator, or an antenna. (Antenna) et al. The antenna may be a liquid crystal antenna or a varactor diode antenna. The sensing device may be a sensing device that senses capacitance, light, heat energy, or ultrasonic waves, but not limited thereto. In the disclosure, the electronic device may include electronic components, and the electronic components may include passive components and active components, such as capacitors, resistors, inductors, diodes, transistors. Diodes may include light-emitting diodes, varactor diodes, or photodiodes. The light-emitting diode may include, for example, an organic light-emitting diode (OLED), a sub-millimeter light-emitting diode (mini-LED), a micro light-emitting diode (micro-LED), or a quantum dot light-emitting diode (quantum dot LED), but not limited thereto. The splicing device may be, for example, a display splicing device or an antenna splicing device, but not limited thereto. It should be noted that the electronic device can be any combination of the above, but not limited thereto. The packaging device may be suitable for Wafer-Level Package (WLP) technology or Panel-Level Package (PLP) technology, such as chip first or RDL first process. In addition, the shape of the electronic device may be a rectangular shape, a circular shape, a polygonal shape, a shape with curved edges, or other suitable shapes. Electronic devices may have peripheral systems such as drive systems, control systems, and light source systems to support display devices, antenna devices, wearable devices (e.g., including augmented reality or virtual reality), vehicle-mounted devices (e.g., including car windshields), or splicing devices.

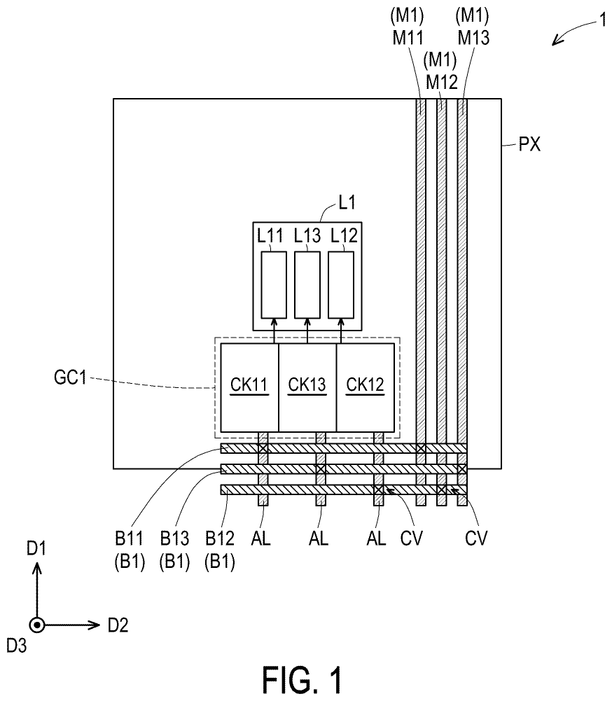

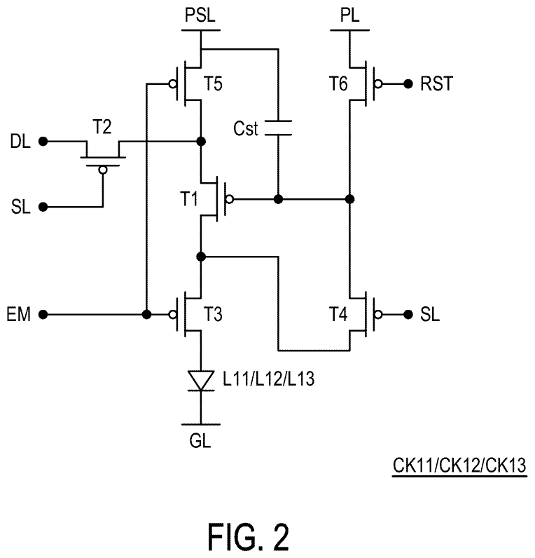

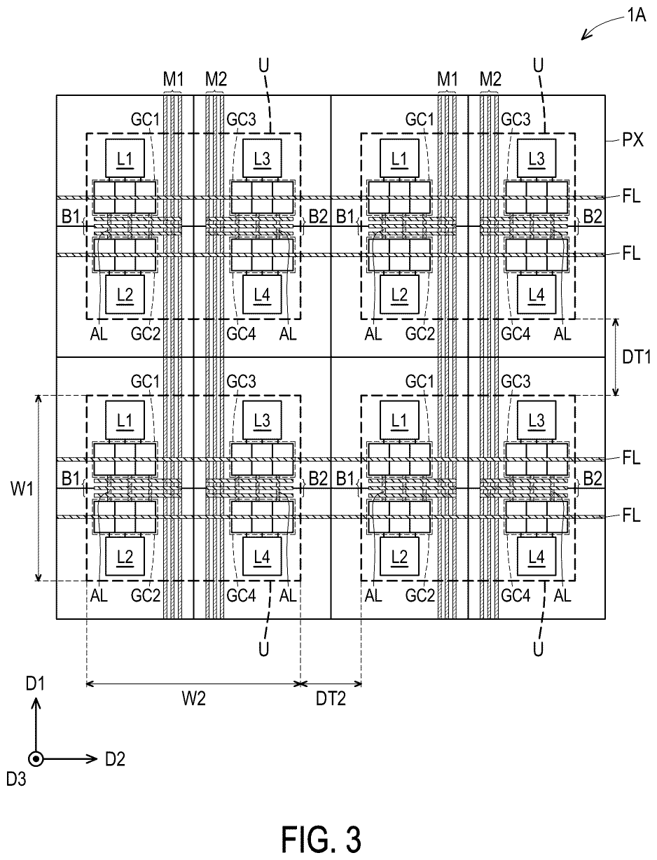

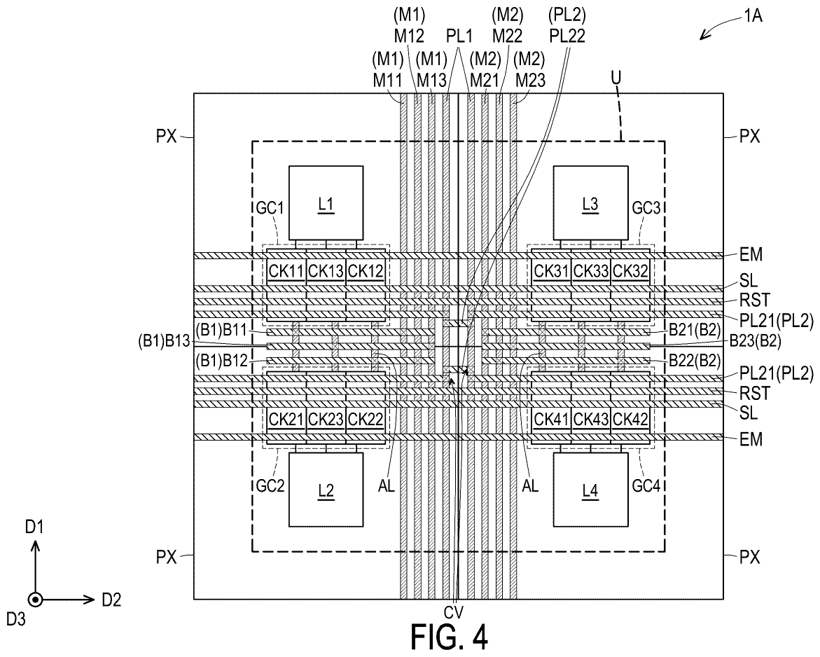

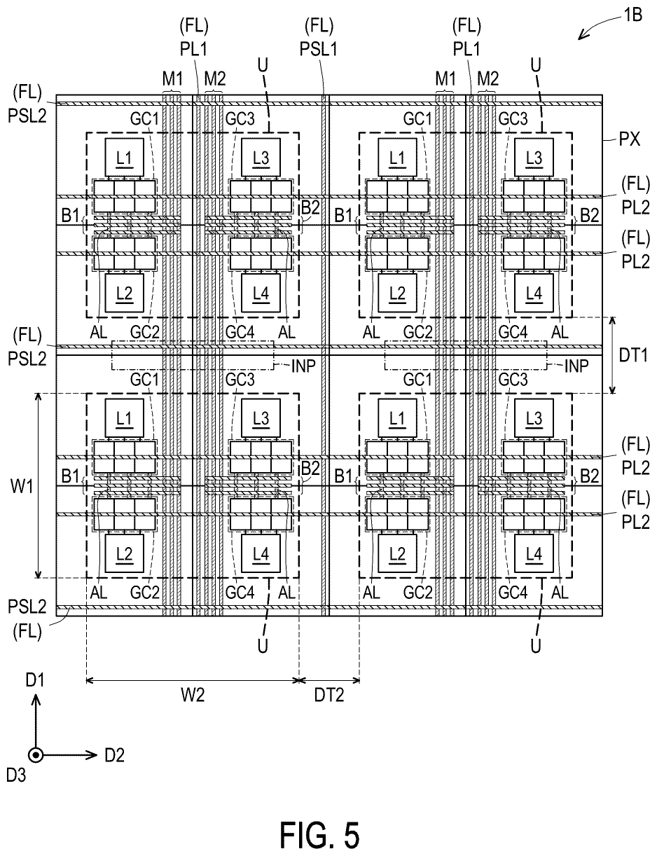

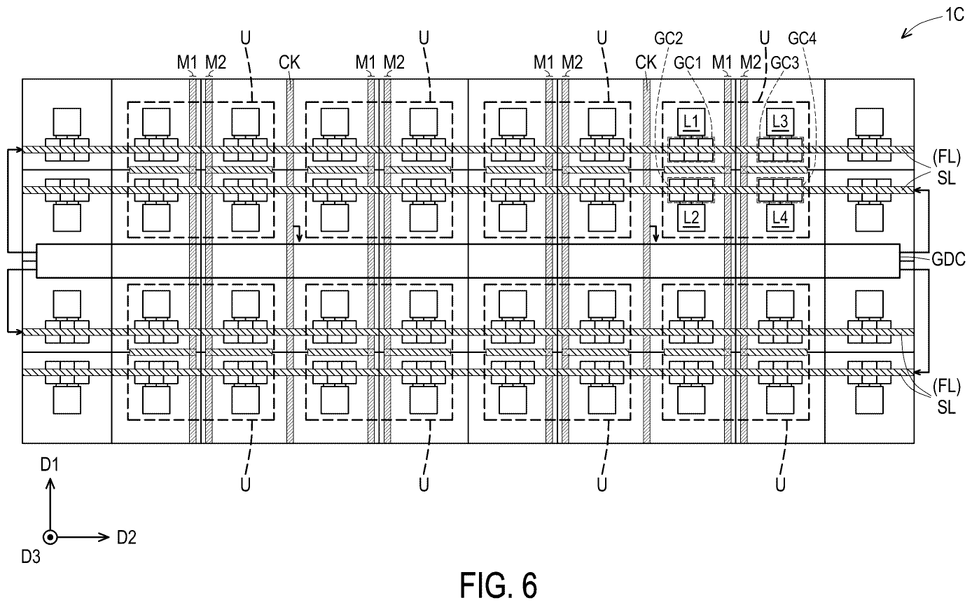

FIG. 1 is a partial top view of an electronic device according to some embodiments of the disclosure. FIG. 2 is a simple circuit diagram of a circuit in FIG. 1. FIG. 3 is a partial top view of an electronic device according to some embodiments of the disclosure. FIG. 4 is an enlarged view corresponding to four pixels in FIG. 3. FIG. 5 is a partial top view of an electronic device according to some embodiments of the disclosure. FIG. 6 is a partial top view of an electronic device according to some embodiments of the disclosure. In top views of the present disclosure, some elements or layers are not shown for simplicity and clarity of the top views. However, the electronic device may include elements or layers not shown in the top view if in need. It should be noted that the following embodiments can be replaced, reorganized, and mixed with features of several different embodiments without departing from the spirit of the disclosure to complete other embodiments. Features in various embodiments may be mixed and matched as long as they do not violate the spirit of the invention or conflict with each other.

Please refer to FIG. 1, an electronic device 1 may include a plurality of first main lines M1, a plurality of first branch lines B1 and a first circuit group GC1. The plurality of first main lines M1 extend along a first direction D1. The plurality of first branch lines B1 are respectively electrically connected to the plurality of first main lines M1 and extend along a second direction D2 perpendicular to the first direction D1. The first circuit group GC1 is disposed on a side (e.g., left side) of the plurality of first main lines M1 and includes a first circuit (e.g., a circuit CK11) and a second circuit (e.g., a circuit CK12). The first circuit (the circuit CK11) is electrically connected to one (e.g., a first branch line B11) of the plurality of first branch lines B1. The second circuit (the circuit CK12) is electrically connected to another one (e.g., a first branch line B12) of the plurality of first branch lines B1. The first circuit (the circuit CK11) and the second circuit (the circuit CK12) are arranged along the second direction D2.

Specifically, FIG. 1 schematically illustrates a pixel PX and wirings (including the plurality of first main lines M1 and the plurality of first branch lines B1) in the peripheral of the pixel PX. In some embodiments, the electronic device 1 can be a light emitting device, such as a micro light emitting device, but not limited thereto. For example, the electronic device 1 can further include a first light emitting unit L1 electrically connected to the first circuit group GC1, wherein the first light emitting unit L1 is disposed on the side (e.g., left side) of the plurality of first main lines M1, and the first light emitting unit L1 and the plurality of first branch lines B1 may be disposed on opposite sides (e.g., upper and lower sides) of the first circuit group GC1. Namely, the first circuit group GC1 may be disposed between the first light emitting unit L1 and the plurality of first branch lines B1.

In some embodiments, the first light emitting unit L1 can include a first light emitting element L11 and a second light emitting element L12 respectively electrically connected to the first circuit (the circuit CK11) and the second circuit (the circuit CK12). Optionally, as shown in FIG. 1, the first light emitting unit L1 can further include a third light emitting element L13, and the first circuit group GC1 can further includes a circuit CK13 electrically connected to the third light emitting element L13. In some embodiments, as shown in FIG. 1, the third light emitting element L13 can be disposed between the first light emitting element L11 and the second light emitting element L12, and the circuit CK13 can be disposed between the circuit CK11 and the circuit CK12, but not limited thereto. In some alternative embodiments, the first light emitting element L11, the second light emitting element L12 and the third light emitting element L13 may be disposed sequentially along the second direction D2, and the circuit CK11, the circuit CK12 and the circuit CK13 may be disposed sequentially along the second direction D2.

The number of the plurality of first main lines M1 and the number of the plurality of first branch lines B1 can both be three, and each circuit can be electrically connected to a corresponding first main line through a corresponding first branch line. For example, as shown in FIG. 1, the circuit CK11 can be electrically connected to the first main line M11 through the first branch line B11, the circuit CK12 can be electrically connected to the first main line M12 through the first branch line B12, and the circuit CK13 can be electrically connected to the first main line M13 through the first branch line B13.

In some embodiments, the first light emitting unit L11, the second light emitting element L12 and the third light emitting element L13 are respectively red, green and blue micro light emitting elements, the circuit CK11, the circuit CK12 and the circuit CK13 are micro light emitting element driving circuits, and the plurality of first main lines M1 and the plurality of first branch lines B1 are data lines used to transmit data signals, but not limited thereto. In some embodiments, the plurality of first main lines M1 belong to a first patterned conductive layer, and the plurality of first branch lines B1 belong to a second patterned conductive layer. The second patterned conductive layer is overlapped with the first patterned conductive layer along a third direction D3 perpendicular to the first direction D1 and the second direction D2. At least one insulating layer (not shown in FIG. 1) may be disposed between the first patterned conductive layer and the second patterned conductive layer, and each first main line can be electrically connected to a corresponding first branch line through a conductive via CV penetrating the at least one insulating layer.

In some embodiments, as shown in FIG. 1, the electronic device 1 can further include a plurality of auxiliary lines AL, wherein each of the circuits (including the circuit CK11, the circuit CK12 and the circuit CK13) can be electrically connected to a corresponding first branch line through a corresponding auxiliary line AL. In some embodiments, the plurality of auxiliary lines AL belong to the first patterned conductive layer (i.e., the plurality of auxiliary lines AL and the plurality of first main lines M1 can be formed together), and each auxiliary line AL can be electrically connected to a corresponding first branch line through a conductive via CV penetrating the at least one insulating layer.

Each of the circuits (including the circuit CK11, the circuit CK12 and the circuit CK13) in the first circuit group GC1 may include one or more active elements and one or more passive elements. For example, as shown in FIG. 2, each of the circuits may include six transistors and one capacitor (also referred to as “6T1C”). Specifically, each of the circuits (including the circuit CK11, the circuit CK12 and the circuit CK13) in the first circuit group GC1 may include a transistor T1, a transistor T2, a transistor T3, a transistor T4, a transistor T5, a transistor T6, and a storage capacitor Cst. Each of the transistors has a first terminal, a second terminal and a third terminal, wherein the first terminal is a gate terminal, one of the second terminal and the third terminal is a source terminal, and the other one of the second terminal and the third terminal is a drain terminal.

As shown in FIG. 2, the first terminal of the transistor T1 may be electrically connected to an end of the storage capacitor Cst, the third terminal of the transistor T4 and the second terminal of the transistor T6. The second terminal of the transistor T1 may be electrically connected to the second terminal of the transistor T3 and the second terminal of the transistor T4. The third terminal of the transistor T1 may be electrically connected to the third terminal of the transistor T2 and the third terminal of the transistor T5. The first terminal of the transistor T2 may be electrically connected to a scan line SL. The second terminal of the transistor T2 may be electrically connected to a data line DL (e.g., one of the plurality of first main lines M1). The first terminal of the transistor T3 may be electrically connected to an emission control line EM. The third terminal of the transistor T3 may be electrically connected to a corresponding light emitting element (e.g., the first light emitting element L11, the second light emitting element L12, or the third light emitting element L13). The first terminal of the transistor T4 may be electrically connected to the scan line SL. The first terminal of the transistor T5 may be electrically connected to the emission control line EM. The second terminal of the transistor T5 may be electrically connected to the other end of the storage capacitor Cst and a power supply line PSL that provides a power supply voltage (e.g., PVDD). The first terminal of the transistor T6 may be electrically connected to a reset line RST. The third terminal of the transistor T6 may be electrically connected to a power line PL that provides a power voltage (e.g., VRST). The corresponding light emitting element (e.g., the first light emitting element L11, the second light emitting element L12, or the third light emitting element L13) may be electrically connected between the third terminal of the transistor T3 and a ground line GL that provides a ground voltage (e.g., PVSS).

It should be understood that FIG. 2 is only a schematic diagram of one embodiment of the circuit, and other circuit structures may also be implemented.

Please refer to FIG. 3 and FIG. 4, in addition to the plurality of first main lines M1, the plurality of first branch lines B1, the first circuit group GC1 and the first light emitting unit L1 described above, an electronic device 1A can further include a second circuit group GC2 disposed on the side (e.g., left side) of the plurality of first main lines M1. The second circuit group GC2 may include a third circuit (e.g., a circuit CK21) electrically connected to the one (e.g., the first branch line B11) of the plurality of first branch lines B1 and a fourth circuit (e.g., a circuit CK22) electrically connected to the another one (e.g., the first branch line B12) of the plurality of first branch lines B1, and the plurality of first branch lines B1 may be disposed between the first circuit group GC1 and the second circuit group GC2. For example, as shown in FIG. 3 or FIG. 4, the first circuit group GC1 and the second circuit group GC2 are arranged along the first direction D1. In some embodiments, as shown in FIG. 3 or FIG. 4, the second circuit group GC2 can further include a circuit CK23 electrically connected to the first branch line B13 of the plurality of first branch lines B1. Each of the circuits (including the circuit CK21, the circuit CK22 and the circuit CK23) in the second circuit group GC2 may include one or more active elements and one or more passive elements. Please refer to the relevant description of FIG. 2 for details, which will not be repeated here. In some embodiments, as shown in FIG. 3 or FIG. 4, each of the circuits (including the circuit CK21, the circuit CK22 and the circuit CK23) in the second circuit group GC2 may be electrically connected to a corresponding first branch line through a corresponding auxiliary line AL.

In embodiments in which the plurality of first branch lines B1 are shared by the first circuit group GC1 and the second circuit group GC2, the wiring space between the first circuit group GC1 and the second circuit group GC2 can be reduced to free up more space for arranging other functional circuits.

In some embodiments, the electronic device 1A can further include a second light emitting unit L2 electrically connected to the second circuit group GC2, wherein the first light emitting unit L1 and the second light emitting unit L2 are disposed on the side (e.g., left side) of the plurality of first main lines M1, the first light emitting unit L1 is disposed on a side (e.g., upper side) of the first circuit group GC1 away from the plurality of first branch lines B1, and the second light emitting unit L2 is disposed on a side (e.g., lower side) of the second circuit group GC2 away from the plurality of first branch lines B1. Namely, the first circuit group GC1, the plurality of first branch lines B1 and the second circuit group GC2 may be disposed between the first light emitting unit L1 and the second light emitting unit L2.

In some embodiments, the second light emitting unit L2 may also include three light emitting elements (not shown in FIG. 3 or FIG. 4) respectively electrically connected to the circuit CK21, the circuit CK22 and the circuit CK23. Please refer to the relevant description of FIG. 1 for details, which will not be repeated here.

In some embodiments, the electronic device 1A can further include a plurality of second main lines M2, a plurality of second branch lines B2 and a third circuit group GC3. The plurality of second main lines M2 may extend along the first direction D1. The plurality of second branch lines B2 may be respectively electrically connected to the plurality of second main lines M2 and may extend along the second direction D2. The third circuit group GC3 may be disposed on a side (e.g., right side) of the plurality of second main lines M2 away from the plurality of first main lines M1. The third circuit group GC3 may include a fifth circuit (e.g., a circuit CK31) electrically connected to one (e.g., a second branch line B21) of the plurality of second branch lines B2 and a sixth circuit electrically (e.g., a circuit CK32) connected to another one (e.g., a second branch line B22) of the plurality of second branch lines B2. The plurality of first main lines M1 and the plurality of second main lines M2 are disposed between the first circuit group GC1 and the third circuit group GC3. For example, as shown in FIG. 3 or FIG. 4, the first circuit group GC1 and the third circuit group GC3 are arranged along the second direction D2. In some embodiments, as shown in FIG. 4, the third circuit group GC3 can further include a circuit CK33 electrically connected to the second branch line B23 of the plurality of second branch lines B2. Each of the circuits (including the circuit CK31, the circuit CK32 and the circuit CK33) in the third circuit group GC3 may include one or more active elements and one or more passive elements. Please refer to the relevant description of FIG. 2 for details, which will not be repeated here. In some embodiments, as shown in FIG. 3 or FIG. 4, each of the circuits (including the circuit CK31, the circuit CK32 and the circuit CK33) in the third circuit group GC3 may be electrically connected to a corresponding second branch line through a corresponding auxiliary line AL.

In some embodiments, the plurality of second main lines M2 belong to the first patterned conductive layer (i.e., the plurality of second main lines M2, the plurality of auxiliary lines AL and the plurality of first main lines M1 can be formed together), while the plurality of second branch lines B2 belong to the second patterned conductive layer (i.e., the plurality of second branch lines B2 and the plurality of first branch lines B1 can be formed together), wherein each of the plurality of second main lines M2 (including a second main line M21, a second main line M22 and a second main line M23) can be respectively electrically connected to a corresponding second branch line (e.g., a second branch line B21, a second branch line B22 or a second branch line B23) through a conductive via CV, and each auxiliary line AL can be electrically connected to a corresponding second branch line through a conductive via CV.

In some embodiments, the electronic device 1A can further include a fourth circuit group GC4 disposed on the side (e.g., right side) of the plurality of second main lines M2 away from the plurality of first main lines M1. The fourth circuit group GC4 may include a seventh circuit (e.g., a circuit CK41) electrically connected to the one (e.g., the second branch line B21) of the plurality of second branch lines B2 and an eighth circuit (e.g., a circuit CK42) electrically connected to the another one (e.g., the second branch line B22) of the plurality of second branch lines B2, wherein the plurality of second branch lines B2 are disposed between the third circuit group GC3 and the fourth circuit group GC4, and the plurality of first main lines M1 and the plurality of second main lines M2 are further disposed between the second circuit group GC2 and the fourth circuit group GC4. For example, as shown in FIG. 4, the third circuit group GC3 and the fourth circuit group GC4 are arranged along the first direction D1, and the second circuit group GC2 and the fourth circuit group GC4 are arranged along the second direction D2. In some embodiments, as shown in FIG. 4, the fourth circuit group GC4 can further include a circuit CK43 electrically connected to the second branch line B23 of the plurality of second branch lines B2. Each of the circuits (including the circuit CK41, the circuit CK42 and the circuit CK43) in the fourth circuit group GC4 may include one or more active elements and one or more passive elements. Please refer to the relevant description of FIG. 2 for details, which will not be repeated here. In some embodiments, as shown in FIG. 3 or FIG. 4, each of the circuits (including the circuit CK41, the circuit CK42 and the circuit CK43) in the fourth circuit group GC4 may be electrically connected to a corresponding second branch line through a corresponding auxiliary line AL.

In embodiments in which the plurality of second branch lines B2 are shared by the third circuit group GC3 and the fourth circuit group GC4, the wiring space between the third circuit group GC3 and the fourth circuit group GC4 can be reduced to free up more space for arranging other functional circuits.

In some embodiments, the electronic device 1A can further include a third light emitting unit L3 electrically connected to the third circuit group GC3 and a fourth light emitting unit L4 electrically connected to the fourth circuit group GC4, wherein the third light emitting unit L3 and the fourth light emitting unit L4 are disposed on the side (e.g., right side) of the plurality of second main lines M2 away from the plurality of first main lines M1, the third light emitting unit L3 is disposed on a side (e.g., upper side) of the third circuit group GC3 away from the plurality of second branch lines B2, and the fourth light emitting unit L4 is disposed on a side (e.g., lower side) of the fourth circuit group GC4 away from the plurality of second branch lines B2. Namely, the third circuit group GC3, the plurality of second branch lines B2 and the fourth circuit group GC4 may be disposed between the third light emitting unit L3 and the fourth light emitting unit L4.

In some embodiments, the third light emitting unit L3 may also include three light emitting elements (not shown in FIG. 3 or FIG. 4) respectively electrically connected to the circuit CK31, the circuit CK32 and the circuit CK33, and the fourth light emitting unit L4 may also include three light emitting elements (not shown in FIG. 3 or FIG. 4) respectively electrically connected to the circuit CK41, the circuit CK42 and the circuit CK43. Please refer to the relevant description of FIG. 1 for details, which will not be repeated here.

In some embodiments, as shown in FIG. 3, the electronic device 1A can further include a plurality of units U arranged in an array along the first direction D1 and the second direction D2, wherein each of the plurality of units U includes the plurality of first branch lines B1, the first circuit group GC1, the second circuit group GC2, the plurality of second branch lines B2, the third circuit group GC3, the fourth circuit group GC4, the first light emitting unit L1, the second light emitting unit L2, the third light emitting unit L3 and the fourth light emitting unit L4. FIG. 3 schematically illustrates four units U, but the electronic device 1A may include more than four units U.

By concentrating the elements and/or circuits in four adjacent pixels PX in the central region (e.g., the region circled by the thick dashed frame representing the unit U) of the four adjacent pixels PX, the peripheral region (e.g., the region outside the thick dashed frame) of the four adjacent pixels PX can be left empty to dispose functional circuits. Since the plurality of first branch lines B1 are shared by the first circuit group GC1 and the second circuit group GC2 and the plurality of second branch lines B2 are shared by the third circuit group GC3 and the fourth circuit group GC4, a width W1 of the unit U along the first direction D1 can be reduced. For example, the width W1 of the unit U along the first direction D1 may be smaller than a width W2 of the unit U along the second direction D2. Therefore, in some embodiments, as shown in FIG. 3, a distance DT1 between two adjacent units U arranged along the first direction D1 is larger than a distance DT2 between two adjacent units U arranged along the second direction D2. In some alternative embodiments, although not shown, W1>W2, and DT1<DT2.

In some embodiments, as shown in FIG. 3, the electronic device 1A can further include one or more functional lines FL extend along the second direction D2 and/or the first direction D1. For example, as shown in FIG. 4, the electronic device 1A can further include a first power line PL1 extending along the first direction D1 and crossing a column of units U (i.e., units U arranged along the first direction D1; only one unit U is shown in FIG. 4) and a second power line PL2 electrically connected to the first power line PL1, extending along the second direction D2 and crossing a row of units U (i.e., units U arranged along the second direction D2; only one unit U is shown in FIG. 4).

In some embodiments, as shown in FIG. 4, the first power line PL1 may be disposed between the plurality of first main lines M1 and the plurality of second main lines M2. In some embodiments, as shown in FIG. 4, the electronic device 1A can include more than one first power lines PL1 and more than one second power lines PL2. In some embodiments, as shown in FIG. 4, the second power line PL2 (e.g., the upper second power line PL2 in FIG. 4) may cross the first circuit groups GC1 and the third circuit groups GC3 of the row of units U (i.e., units U arranged along the second direction D2; only one unit U is shown in FIG. 4). In some embodiments, as shown in FIG. 4, the second power line PL2 (e.g., the lower second power line PL2 in FIG. 4) may cross the second circuit groups GC2 and the fourth circuit groups GC4 of the row of units U (i.e., units U arranged along the second direction D2; only one unit U is shown in FIG. 4).

In some embodiments, as shown in FIG. 4, the second power line PL2 is broken into multiple portions. For example, the second power line PL2 may include a plurality of first portions PL21 and a plurality of second portions PL22 not aligned with the plurality of first portions PL21 along the second direction D2, wherein the plurality of first portions PL21 and the plurality of second portions PL22 may be alternately arranged along the second direction D2. The first portion PL21 may cross the plurality of first main lines M1, one first circuit group GC1 (or one second circuit group GC2), one third circuit group GC3 (or one fourth circuit group GC4) and the plurality of second main lines M2 to electrically connect two first power lines PL1 that cross two adjacent units U. The second portion PL22 may electrically connect two adjacent first power lines PL1 that cross the same unit U. By electrically connecting multiple power lines (e.g., the first power lines PL1 and the second power line PL2) together, a uniform constant potential can be provided and/or impedance (or loading) of the power lines can be reduced.

In some embodiments, as shown in FIG. 4, the first power lines PL1 belong to the first patterned conductive layer (i.e., the first power lines PL1, the plurality of second main lines M2, the plurality of auxiliary lines AL and the plurality of first main lines M1 can be formed together), while the second power lines PL2 belong to the second patterned conductive layer (i.e., the second power lines PL2, the plurality of second branch lines B2 and the plurality of first branch lines B1 can be formed together), wherein the second power line PL2 can be electrically connected to the first power lines PL1 through the plurality of conductive vias CV.

For example, as shown in FIG. 4, the electronic device 1A can further include a plurality of emission control lines EM extending along the second direction D2 and arranged along the first direction D1. Two adjacent emission control lines EM may cross a row of units U. For example, the plurality of first branch lines B1 and the plurality of second branch lines B2 of the row of units U may be disposed between the two adjacent emission control lines EM, wherein one of the two adjacent emission control lines EM crosses the first circuit groups GC1 and the third circuit groups GC3 of the row of units U, and the other one of the two adjacent emission control lines EM crosses the second circuit group GC2 and the fourth circuit groups GC4 of the row of units U. The plurality of emission control lines EM may belong to the second patterned conductive layer (i.e., the plurality of emission control lines EM, the second power lines PL2, the plurality of second branch lines B2 and the plurality of first branch lines B1 can be formed together). In some alternative embodiments, the plurality of second branch lines B2 and the plurality of first branch lines B1 may belong to the second patterned conductive layer, and the plurality of emission control lines EM and the second power line PL2 may belong to a third patterned conductive layer.

For example, as shown in FIG. 4, the electronic device 1A can further include a plurality of scan lines SL and a plurality of reset lines RST. The details (e.g., configuration, belonged layer, etc.) of the plurality of scan lines SL and the plurality of reset lines RST are similar to that of the plurality of emission control lines EM, which will not be repeated here.

In FIG. 4, the second power line PL2, the reset line RST, the scan line SL and the emission control line EM are sequentially arranged in a direction (e.g., the first direction or the direction opposite thereof) away from the plurality of first branch lines B1 and the plurality of second branch lines B2, but the disclosure is not limited thereto. In addition, the type and/or number of the functional lines FL in FIG. 3 are not limited. For example, the functional lines FL may include more or fewer functional lines than those shown in FIG. 4.

Please refer to FIG. 5, in addition to the plurality of first main lines M1, the plurality of second main lines M2, the plurality of units U and the functional lines FL described above, an electronic device 1B can further include an inspection circuit INP disposed between two adjacent rows of units U. In some embodiments, as shown in FIG. 5, the electronic device 1B can include more than one inspection circuits INP. In some alternative embodiments, although not shown in FIG. 5, other components may be disposed between two adjacent rows of units U. For example, ESD protection diodes or systems; process control mark set; process inspection/verification pattern; signal fanout pattern; monitor lines; GOP control signal lines; power lines; distinguish mark, words, letters, patterns or the like; test-key (e.g., test element group (TEG), device under test (DUT), etc.); through hole vias within substrate (e.g., THV, TGV, etc.); circuit group(s); functional lines FL; auxiliary lines AL; and/or combination of at least two of the above may be disposed between two adjacent rows of units U, but not limited thereto.

In some embodiments, as shown in FIG. 5, the electronic device 1B can further include a first power supply line PSL1 disposed between two adjacent columns of units U and a second power supply line PSL2 electrically connected to the first power supply line PSL1 and disposed between two adjacent rows of units U. In some embodiments, the electronic device 1B can further include more than one first power supply lines PSL1 (only one is shown) and more than one second power supply lines PSL2. In some embodiments, the first power supply lines PSL1 belong to the first patterned conductive layer while the second power supply lines PSL2 belong to the second patterned conductive layer, wherein the second power supply lines PSL2 can be electrically connected to the first power supply lines PSL1 through the plurality of conductive vias CV.

As described above, the layout space extending along the second direction D2 (e.g., the layout space between two adjacent rows of units U) can be wider/larger than the layout space extending along the first direction D1 (e.g., the layout space between two adjacent columns of units U). Therefore, functional circuits or wirings requiring a larger space can be disposed between two adjacent rows of units U, while functional circuits or wirings requiring a smaller space can be disposed between two adjacent columns of units U. For example, although not shown in FIG. 5, a gate driving circuit (e.g., a gate driver on panel (GOP) circuit), additional power lines, additional power supply lines, ESD protection circuits, contact pads for side-wiring or bonding to COF (Chip On Film) or FPC (Flexible Printed Circuit), other circuits and/or wirings may be disposed in the layout space extending along the second direction D2, while clock signal lines for GOP circuits, additional power lines, additional power supply lines, other circuits and/or wirings may be disposed in the layout space extending along the first direction D1, but not limited thereto. For example, although not shown in FIG. 5, the contact pads for side-wiring or bonding to COF (Chip On Film) or FPC (Flexible Printed Circuit) may be disposed in the layout space extending along the first direction D1 and/or the second direction D2. For example, although not shown in FIG. 5, through glass vias (TGV) and/or through hole vias (THV) within substrate (e.g., PI, glass or the like) may be disposed in the layout space extending along the first direction D1, the second direction D2 and/or corner(s) of the pixels PX.

Please refer to FIG. 6, in addition to the plurality of first main lines M1, the plurality of second main lines M2, the plurality of units U and the functional lines FL described above, an electronic device 1C can further include a gate driving circuit GDC disposed between two adjacent rows of units U, wherein the gate driving circuit GDC is configured to provide a gate signal to the first circuit group GC1, the second circuit group GC2, the third circuit group GC3 and the fourth circuit group GC4. In some embodiments, as shown in FIG. 6, the gate driving circuit GDC is disposed on a side (e.g., lower side) of the second circuit group GC2 away from the first circuit group GC1.

In some embodiments, as shown in FIG. 6, the electronic device 1C can further include a clock signal line CK disposed between two adjacent columns of units U and electrically connected to the gate driving circuit GDC. In some embodiments, the clock signal line CK is disposed on a side (e.g., left side) of the first circuit group GC1 and the second circuit group GC2 away from the plurality of first main lines M1. In some embodiments, the electronic device 1C can include more than one clock signal lines CK. In some embodiments, the clock signal lines CK belong to the first patterned conductive layer, but not limited thereto.

By disposing the clock signal lines CK away from the data lines (e.g., the plurality of first main lines M1 and/or the plurality of second main lines M2), line defects (or grayscale shift) caused by coupling between the clock signal lines CK and the data lines can be reduced, thereby improving the display quality.

In summary, in the embodiments of the disclosure, a narrow-border or even borderless electronic device can be achieved by the proposed layout design.

The above embodiments are only used to illustrate the technical solution of the disclosure, but not to limit it; although the disclosure has been described in detail with reference to the foregoing embodiments, those of ordinary skill in the art should understand that they can still modify the technical solutions recorded in the foregoing embodiments, or make equivalent substitutions for some or all of the technical features. However, these modifications or substitutions do not cause the essence of the corresponding technical solution to deviate from the scope of the technical solution of each embodiment of the disclosure.

Although the embodiments and advantages of the disclosure have been disclosed above, it should be understood that anyone with ordinary skill in the art can make changes, substitutions and modifications without departing from the spirit and scope of the disclosure. Furthermore, the features of various embodiments can be mixed and replaced at will to form other new embodiments. In addition, the protection scope of the disclosure is not limited to the processes, machines, manufacturing, material compositions, devices, methods and steps in the specific embodiments described in the specification. Any process, machine, manufacture, material compositions, device, method, and steps, now or hereafter developed, which may be understood from this disclosure by any person having ordinary knowledge in the art, may be used in accordance with this disclosure, provided that substantially the same function can be performed, or substantially the same result can be obtained, in the embodiments described herein. Accordingly, the scope of protection of the disclosure includes the processes, machines, manufacturing, material compositions, devices, methods, and steps described above. In addition, each claim constitutes an individual embodiment, and the scope of protection of the disclosure also includes a combination of the claims and embodiments. The scope of protection of the disclosure shall be as defined in the scope of the patent application attached hereto.

Anyone with ordinary knowledge in the relevant technical field can learn from the disclosure that processes, machines, manufacturing, material compositions, devices, methods and steps currently or developed in the future can be used according to the present disclosure as long as they can perform substantially the same functions or obtain substantially the same results in the embodiments described herein. Therefore, the protection scope of the present disclosure includes the above-mentioned processes, machines, manufacturing, material compositions, devices, methods and steps. In addition, each claim constitutes an individual embodiment, and the protection scope of the present disclosure also includes combinations of each claim and embodiment. The scope of protection of this disclosure shall be determined by the scope of the accompanying patent application.

What is claimed is:

1. An electronic device, comprising:
a plurality of first main lines extending along a first direction;
a plurality of first branch lines respectively electrically connected to the plurality of first main lines and extending along a second direction perpendicular to the first direction; and
a first circuit group disposed on a side of the plurality of first main lines and comprising:
a first circuit electrically connected to one of the plurality of first branch lines; and
a second circuit electrically connected to another one of the plurality of first branch lines,
wherein the first circuit and the second circuit are arranged along the second direction.

2. The electronic device according to claim 1, further comprising:
a first light emitting unit electrically connected to the first circuit group, wherein the first light emitting unit is disposed on the side of the plurality of first main lines, and the first light emitting unit and the plurality of first branch lines are disposed on opposite sides of the first circuit group.

3. The electronic device according to claim 2, wherein the first light emitting unit comprises a first light emitting element and a second light emitting element respectively electrically connected to the first circuit and the second circuit.

4. The electronic device according to claim 1, further comprising:
a second circuit group disposed on the side of the plurality of first main lines and comprising:
a third circuit electrically connected to the one of the plurality of first branch lines; and
a fourth circuit electrically connected to the another one of the plurality of first branch lines,
wherein the plurality of first branch lines are disposed between the first circuit group and the second circuit group.

5. The electronic device according to claim 4, further comprising:
a first light emitting unit electrically connected to the first circuit group; and
a second light emitting unit electrically connected to the second circuit group, wherein:
the first light emitting unit and the second light emitting unit are disposed on the side of the plurality of first main lines,
the first light emitting unit is disposed on a side of the first circuit group away from the plurality of first branch lines, and
the second light emitting unit is disposed on a side of the second circuit group away from the plurality of first branch lines.

6. The electronic device according to claim 4, further comprising:
a plurality of second main lines extending along the first direction;
a plurality of second branch lines respectively electrically connected to the plurality of second main lines and extending along the second direction; and
a third circuit group disposed on a side of the plurality of second main lines away from the plurality of first main lines and comprising:
a fifth circuit electrically connected to one of the plurality of second branch lines; and
a sixth circuit electrically connected to another one of the plurality of second branch lines,
wherein the plurality of first main lines and the plurality of second main lines are disposed between the first circuit group and the third circuit group.

7. The electronic device according to claim 6, further comprising:
a fourth circuit group disposed on the side of the plurality of second main lines away from the plurality of first main lines and comprising:
a seventh circuit electrically connected to the one of the plurality of second branch lines; and
an eighth circuit electrically connected to the another one of the plurality of second branch lines,
wherein the plurality of second branch lines are disposed between the third circuit group and the fourth circuit group, and the plurality of first main lines and the plurality of second main lines are further disposed between the second circuit group and the fourth circuit group.

8. The electronic device according to claim 7, further comprising:
a first light emitting unit electrically connected to the first circuit group;
a second light emitting unit electrically connected to the second circuit group;
a third light emitting unit electrically connected to the third circuit group; and
a fourth light emitting unit electrically connected to the fourth circuit group, wherein:
the first light emitting unit and the second light emitting unit are disposed on the side of the plurality of first main lines,
the first light emitting unit is disposed on a side of the first circuit group away from the plurality of first branch lines,
the second light emitting unit is disposed on a side of the second circuit group away from the plurality of first branch lines,
the third light emitting unit and the fourth light emitting unit are disposed on the side of the plurality of second main lines away from the plurality of first main lines,
the third light emitting unit is disposed on a side of the third circuit group away from the plurality of second branch lines, and
the fourth light emitting unit is disposed on a side of the fourth circuit group away from the plurality of second branch lines.

9. The electronic device according to claim 8, further comprising:
a plurality of units arranged in an array along the first direction and the second direction, wherein each of the plurality of units comprises the plurality of first branch lines, the first circuit group, the second circuit group, the plurality of second branch lines, the third circuit group, the fourth circuit group, the first light emitting unit, the second light emitting unit, the third light emitting unit and the fourth light emitting unit.

10. The electronic device according to claim 9, wherein a distance between two adjacent units arranged along the first direction is larger than a distance between two adjacent units arranged along the second direction.

11. The electronic device according to claim 9, further comprising:
an inspection circuit disposed between two adjacent rows of units.

12. The electronic device according to claim 9, further comprising:
a gate driving circuit disposed between two adjacent rows of units, wherein the gate driving circuit is configured to provide a gate signal to the first circuit group, the second circuit group, the third circuit group and the fourth circuit group.

13. The electronic device according to claim 12, further comprising:
a clock signal line disposed between two adjacent columns of units and electrically connected to the gate driving circuit.

14. The electronic device according to claim 9, further comprising:
a first power supply line disposed between two adjacent columns of units; and
a second power supply line electrically connected to the first power supply line and disposed between two adjacent rows of units.

15. The electronic device according to claim 9, further comprising:
a first power line extending along the first direction and crossing a column of units; and
a second power line electrically connected to the first power line, extending along the second direction and crossing a row of units.

16. The electronic device according to claim 15, wherein the first power line is disposed between the plurality of first main lines and the plurality of second main lines.

17. The electronic device according to claim 15, wherein the second power line crosses the first circuit groups and the third circuit groups of the row of units.

18. The electronic device according to claim 15, wherein the second power line crosses the second circuit groups and the fourth circuit groups of the row of units.

19. The electronic device according to claim 7, further comprising:
a gate driving circuit disposed on a side of the second circuit group away from the first circuit group, wherein the gate driving circuit is configured to provide a gate signal to the first circuit group, the second circuit group, the third circuit group and the fourth circuit group.

20. The electronic device according to claim 19, further comprising:
a clock signal line disposed on a side of the first circuit group and the second circuit group away from the plurality of first main lines and electrically connected to the gate driving circuit.
